(19) United States
(12) Patent Application Publication
(10) Pub. No.: US 2026/0186028 A1
(43) Pub. Date: Jul. 2, 2026

(54) TECHNIQUES FOR VISUALIZING MULTIPLE TIME DOMAIN REFLECTOMETRY WAVEFORMS

(71) Applicant: Essai, Inc., San Jose, CA (US)

(72) Inventor: Jinlei LIU, Gilroy, CA (US)

(21) Appl. No.: 19/005,833

(22) Filed: Dec. 30, 2024

(51) Int. Cl. G01R 13/02; G01R 31/11; G01R 31/28

(52) U.S. Cl. CPC G01R 13/0281; G01R 31/11; G01R 31/2806

(57) ABSTRACT

Various embodiments include a TDR viewer for visualizing a large number of reflected TDR signals on a 3D display system. The TDR system captures the waveforms for reflected TDR signals that are associated with signal propagation and delay. The TDR viewer displays the signal waveforms as the signals propagate through the transmission lines. The waveforms can display changes in the reflected TDR signals due to transmission between various printed circuit board layers, through component connectors and vias of the printed circuit board, and across the interconnects and socket pins. The 3D visualization of the reflected TDR signals can be rotated in 3D space, zoomed in or out, and filtered to display a subset of signals. The 3D visualization enables a test engineer to more quickly identify TDR signals of interest, including signals with longer or shorter delay times relative to other TDR signals and signals that exhibit undesirable signal attributes.

### BACKGROUND

### Field of the Various Embodiments

Various embodiments relate generally to integrated circuit manufacturing and test and, more specifically, to techniques for visualizing multiple time domain reflectometry waveforms.

### Description of the Related Art

Time domain reflectometry (TDR) is a signal measurement technique that includes transmitting a signal along a transmission line and measuring the signal that is reflected back via the transmission line. The TDR technique involves placing a signal transmitter and a signal receiver at one end of the transmission line. For example, TDR can be used to measure the time delay between transmitting, by the transmitter, a pulse signal, a step signal, or other signal along the transmission line and receiving, by the receiver at the same point where transmitter sits, the corresponding reflected signal. The difference in the time of a particular feature of the transmitted signal and the corresponding feature of the received signal is a measure of the round-trip time of the transmission line. Consequently, one half of this round-trip time is the one-way trip time to transmit the signal from one end of the transmission line to the other end of the transmission line. This one-way time can be converted via a mathematical function to a length of the transmission line.

TDR can be used in a device testing system where multiple transmission lines, such as multiple electrical trace lines on a printed circuit board or load board, connect multiple test signal transmitters to corresponding interconnects, such as spring probes, on a test fixture. In addition, TDR can be used in such a device testing system where a test socket is installed that makes contact with the interconnects and connects the interconnects to corresponding pins on the socket. During a test procedure, the pins on the socket connect to corresponding pins on a device under test (DUT). TDR can be used to measure a first distance between the transmitter and the interconnect and to measure a second distance between the transmitter and the pin on the socket. The difference between the first distance and the second distance is a measure of the distance between the interconnect and the pin on the socket.

In a high-speed test system, it can be advantageous to time the transmitted test signals to arrive at the pins of the socket at the same time. By using transmission line distances measure by TDR, test signals can be transmitted earlier along longer transmission lines and/or transmitted later along shorter transmission lines such that the test signals arrive at the socket pins at the same time. Further, one or more reflected signals can be displayed on a display device to visualize the transmission time and reflected signal attributes, such as overshoot, undershoot, rise times, fall times, and/or the like. These attributes can indicate impedance mismatches, short circuits, open circuits and/or the like.

One drawback with existing visualization techniques for reflected TDR signals is that the TDR signals are overlaid over one another on a two-dimensional (2D) display of voltage (y-axis) over time (x-axis). With such a 2D display, it can be difficult to distinguish the signals from one another, particularly, in cases where a large number of signals, typically over hundreds or over thousands signals in an automatic test system in a high volume production environment, are overlaid together on a single 2D display. It is even more complex where multiple devices on the same test board are present. As a result, diagnosing problems and adjusting transmitter timing for specific transmitters can be extremely cumbersome and difficult, time consuming, and prone to error.

As the foregoing illustrates, what is needed in the art are more effective techniques for visualizing reflected TDR signals in electronic device test systems.

### SUMMARY

Various embodiments of the present disclosure set forth a method. The method includes receiving a plurality of time domain reflectometry (TDR) signals from a test system. The method further includes generating, for each TDR signal included the plurality of TDR signals, a corresponding waveform included in a plurality of waveforms. The method further includes generating a three-dimensional (3D) visualization of the plurality of waveforms. With this method, each waveform included in the plurality of waveforms is at a different offset from all other waveforms included in the plurality of waveforms along one dimension of the 3D visualization.

Other embodiments include, without limitation, a system that implements one or more aspects of the disclosed techniques, and one or more computer readable media including instructions for performing one or more aspects of the disclosed techniques, as well as a method for performing one or more aspects of the disclosed techniques.

At least one technical advantage of the disclosed techniques relative to the prior art is that, with the disclosed techniques, a test engineer can visually observe myriad waveforms concurrently in 3D space. The 3D visualization techniques enable the test engineer to more quickly identify TDR signals of interest, including signals with longer or shorter delay times relative to other TDR signals, signals that exhibit undesirable signal attributes, and/or the like. More specifically, the test engineer can determine if the waveform deviates from a nominal value visually and can determine if the manufacturing process should be improved, whether the printed circuit board and/or interconnects should be repaired or replaced, whether the layout of the transmission lines on the printed circuit board should change, whether the timing of one or more transmitters should be adjusted and/or the like.

Further, the TDR viewer allows the test engineer to select individual transmission lines and/or groups of transmission lines separately, thereby enabling the test engineer to easily compare waveforms for certain transmission lines of interest. The test engineer can quickly identify whether an unusual waveform is indicative of manufacturing issues, layout issues, printed circuit board quality issues, and/or the like. As a result, the test engineer can more quickly and efficiently identify and resolve transmission line problems relative to prior conventional approaches. This improves efficiency in engineering environment and productivity in manufacturing process. This improved efficiency can lead to reduced manufacturing test time, increased utilization of test equipment, reduced power consumption of test equipment, and, therefore, reduced testing cost. These advantages represent one or more technological improvements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 is a block diagram illustrating a computing system, which can be used as a platform and/or as control system configured to implement one or more aspects of the various embodiments;

FIG. 2 illustrates an application loadboard included in computing system of FIG. 1, according to various embodiments;

FIG. 3 is a block diagram illustrating a TDR test circuit included in the computing system of FIG. 1, according to various embodiments;

FIG. 4 illustrates how the TDR test circuit of FIG. 3 can measure a propagation delay of a transmission line when the test socket is disconnected from the application loadboard, according to various embodiments;

FIG. 5 illustrates how the TDR test circuit of FIG. 3 can measure a propagation delay of a transmission line when the test socket is connected to the application loadboard, according to various embodiments;

FIG. 6 illustrates how the TDR test circuit of FIG. 3 can measure a propagation delay of the test socket connected to the application loadboard, according to various embodiments;

FIG. 7 is a 3D visualization of reflected TDR signals when the application loadboard is in a disconnected state, according to various embodiments;

FIG. 8 is a 3D visualization of the reflected TDR signals of FIG. 7 from an alternative view, according to various embodiments;

FIG. 9 is a 3D visualization of reflected TDR signals when the application loadboard is in a connected state, according to various embodiments;

FIG. 10 is a 3D visualization of the reflected TDR signals of FIG. 9 from an alternative view, according to various embodiments;

FIG. 11 is a 3D visualization of reflected TDR signals, according to various embodiments;

FIG. 12 is a 3D visualization of the reflected TDR signals of FIG. 11 from an alternative view when the application loadboard is in a disconnected state, according to various embodiments,

FIG. 13 is a 3D visualization of the reflected TDR signals of FIG. 11 from an alternative view when the application loadboard is in a connected state, according to various embodiments,

FIG. 14 is a 3D visualization of a subset of the reflected TDR signals of FIG. 13, according to various embodiments;

FIG. 15 is a 3D visualization of the subset of the reflected TDR signals of FIG. 14 from an alternative view, according to various embodiments; and

FIG. 16 is a flow diagram of methods steps for generating a 3D visualization of reflected time domain reflectometry signals with the test system of FIGS. 1-3, according to various embodiments.

### DETAILED DESCRIPTION

Various embodiments of the disclosed techniques include a TDR viewer for visualizing a large number of reflected TDR signals on a 3D display system. The TDR system captures the waveforms for reflected TDR signals that are associated with signal propagation and delay. The TDR viewer displays the signal waveforms as the signals propagate through the transmission lines. The waveforms can display changes in the reflected TDR signals due to transmission between various printed circuit board layers, through component connectors and vias of the printed circuit board, and across the interconnects and socket pins. The 3D visualization of the reflected TDR signals can be rotated in 3D space, zoomed in or out, and filtered to display a subset of signals.

In the following description, numerous specific details are set forth to provide a more thorough understanding of the various embodiments. However, it will be apparent to one skilled in the art that the inventive concepts may be practiced without one or more of these specific details.

### System Overview

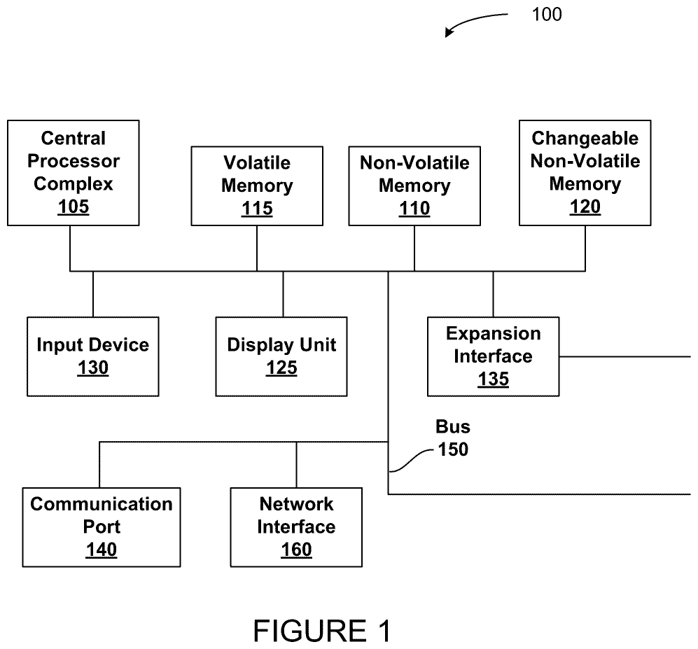

FIG. 1 is a block diagram illustrating a computing system 100, which can be used as a platform and/or as control system configured to implement one or more aspects of the various embodiments. As shown, computing system 100 can be a “server” computer system, in some embodiments. Computing system 100 includes an address/data bus 150 for communicating information, a central processor complex 105 functionally coupled with a bus 150 for processing information and instructions. Bus 150 can comprise, for example, a Peripheral Component Interconnect Express (PCIe) computer expansion bus, industry standard architecture (ISA), extended ISA (EISA), MicroChannel, Multibus, Institute of Electrical and Electronics Engineers (IEEE) 796, IEEE 1196, IEEE 1496, PCI, Computer Automated Measurement and Control (CAMAC), MBus, Runway bus, Compute Express Link (CXL), and the like.

Central processor complex 105 can comprise a single processor or multiple processors, e.g., a multi-core processor, or multiple separate processors, in some embodiments. Central processor complex 105 can comprise various types of well-known processors in any combination, including, without limitation, digital signal processors (DSPs), graphics processors (GPUs), complex instruction set (CISC) processors, reduced instruction set (RISC) processors, very long word instruction set (VLIW) processors, and/or the like. Computing system 100 can also include a volatile memory 115 (e.g., random access memory RAM) coupled with the bus 150 for storing information and instructions for the central processor complex 105, and a non-volatile memory 110 (e.g., read only memory ROM) coupled with the bus 150 for storing static information and instructions for the central processor complex 105. Computing system 100 optionally includes a changeable, non-volatile memory 120 (e.g., NOR flash memory) for storing information and instructions for the central processor complex 105 which can be updated after the manufacture of computing system 100. In some embodiments, only one of non-volatile memory 110 or changeable, non-volatile memory 120 may be present.

Also included in computing system 100 of FIG. 1 is an optional input device 130. Input device 130 can communicate information and command selections to the central processor complex 105. Input device 130 can be any suitable device for communicating information and/or commands to the computing system 100. For example, input device 130 can take the form of a keyboard, buttons, a joystick, a track ball, an audio transducer, e.g., a microphone, a touch sensitive digitizer panel, eyeball scanner, and/or the like.

Computing system 100 can comprise a display unit 125. Display unit 125 can comprise a liquid crystal display (LCD) device, cathode ray tube (CRT), field emission device (FED, also called flat panel CRT), light emitting diode (LED), plasma display device, electro-luminescent (EL) display, electronic paper, electronic ink (e-ink), and/or other display device suitable for creating graphic images and/or alphanumeric characters recognizable to the user. Display unit 125 can have an associated lighting device, in some embodiments.

Computing system 100 also optionally includes an expansion interface 135 coupled with the bus 150. Expansion interface 135 can implement many well-known standard expansion interfaces, including, without limitation, the Secure Digital Card interface, universal serial bus (USB) interface, Compact Flash, Personal Computer (PC) Card interface, CardBus, Peripheral Component Interconnect (PCI) interface, Peripheral Component Interconnect Express (PCI Express), mini-PCI interface, IEEE 8394, Small Computer System Interface (SCSI), Personal Computer Memory Card International Association (PCMCIA) interface, Industry Standard Architecture (ISA) interface, RS-232 interface, and/or the like. In some embodiments of the present disclosure, expansion interface 135 can comprise signals substantially compliant with the signals of bus 150.

A wide variety of well-known devices can be attached to computing system 100 via the bus 150 and/or expansion interface 135. Examples of such devices include without limitation rotating magnetic memory devices, flash memory devices, digital cameras, wireless communication modules, digital audio players, and Global Positioning System (GPS) devices.

Computing system 100 also optionally includes a communication port 140. Communication port 140 can be implemented as part of expansion interface 135. When implemented as a separate interface, communication port 140 can typically be used to exchange information with other devices via communication-oriented data transfer protocols. Examples of communication ports include without limitation RS-232 ports, universal asynchronous receiver transmitters (UARTs), USB ports, infrared light transceivers, ethernet ports, IEEE 8394, and synchronous ports.

Computing system 100 optionally includes a network interface 160, which can implement a wired or wireless network interface. Computing system 100 can comprise additional software and/or hardware features (not shown), in some embodiments.

### 3D Visualization of Multiple Time Domain Reflectometry Waveforms

In some embodiments, computing system 100 can be configured as a test system to test one or more devices under test (DUTs). In such embodiments, computing system 100 can be coupled to an application loadboard. The application loadboard includes one or more mounts, where each mount can accept a test socket. One or more DUTs can be mounted on the one or more test sockets. Computing system 100 can execute a test procedure to test the DUTs mounted on the test sockets. Prior to executing a test procedure on one or more DUTs, computing system 100 can perform TDR measurements using the techniques described herein. A test engineer can use these TDR measurements to determine the propagation delay and/or length of electrical signal traces that connect a signal driver to the application loadboard and, in turn, to the test socket. The test engineer can use these TDR measurements to calibrate the test socket by advancing and/or delaying certain signals from one or more signal drivers so that the signals from the signal drivers arrive at the test socket at the same time. Further, a test engineer can use these TDR measurements to determine whether certain electrical signal traces, certain spring probes on the application loadboard, and/or certain connections on the test socket indicate that the application loadboard and/or the test socket should be repaired or replaced.

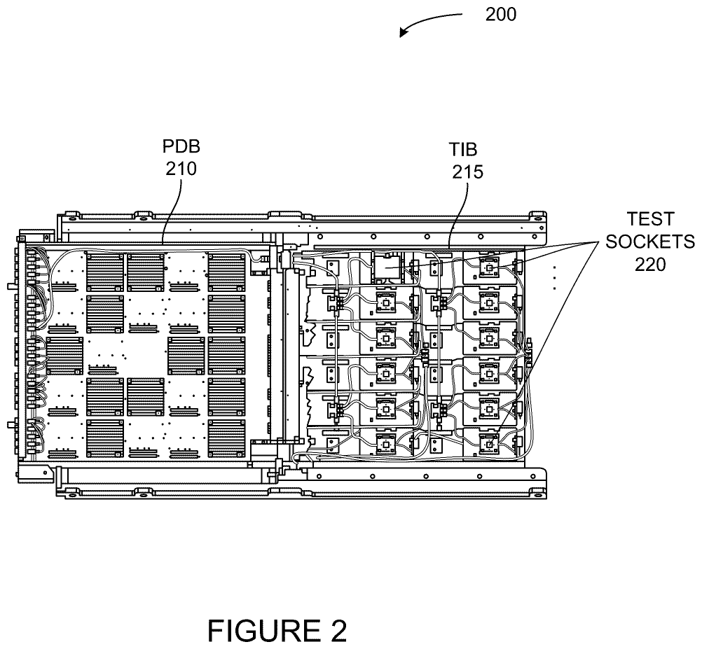

FIG. 2 illustrates an application loadboard 200 included in computing system 100 of FIG. 1, according to various embodiments. Application loadboard 200, and/or any components thereof, can be implemented on one or more computing systems, such as computing system 100 of FIG. 1. As shown, application loadboard 200 includes, without limitation, a power distribution board (PDB) 210 and a test interface board (TIB) 215. Prior to performing a test procedure, test interface board 215 can be attached to power distribution board 210 and, when the test procedure completes, test interface board 215 can be detached from power distribution board 210. Application loadboard 200 can be associated with an automated placement machine (not shown) that can automatically attach test interface board 215 to and/or detach test interface board 215 from power distribution board 210. Additionally or alternatively, a user can manually attach test interface board 215 to and/or detach test interface board 215 from power distribution board 210.

Power distribution board 210 provides electrical power to test interface board 215 to provide power during test procedures and during the TDR measurement techniques described herein. Test interface board 215 of application loadboard 200 includes one or more mounts, where each mount can accept a test socket 220. One or more DUTs can be mounted on the one or more test sockets 220. Computing system 100 can perform TDR measurements on test interface board 215 of application loadboard 200 and on test sockets 220 using the techniques described herein. A test engineer can use these TDR measurements to determine the propagation delay and/or length of electrical signal traces that connect a signal driver to application loadboard 200 and, in turn, to test socket 220. The test engineer can use these TDR measurements to calibrate test socket 220 by advancing and/or delaying certain signals from one or more signal drivers so that the signals from the signal drivers arrive at test socket 220 at the same time. Further, a test engineer can use these TDR measurements to determine whether certain electrical signal traces, certain spring probes on application loadboard 200, and/or certain connections on test socket 220 indicate that application loadboard 200 and/or test socket 220 should be repaired or replaced.

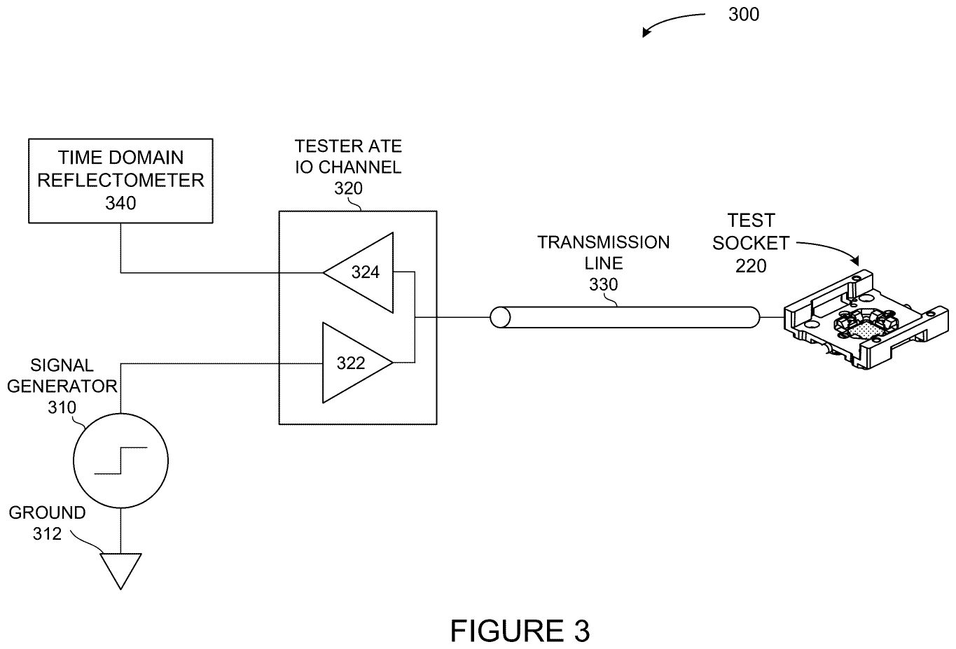

FIG. 3 is a block diagram illustrating a TDR test circuit 300 included in the computing system 100 of FIG. 1, according to various embodiments. TDR test circuit 300, and/or any components thereof, can be implemented on one or more computing systems, such as computing system 100 of FIG. 1. When computing system 100 implements one or more instances of TDR test circuit 300, computing system 100 can be referred to as a test system or, more specifically, as automated test equipment (ATE). As shown, TDR test circuit 300 includes, without limitation, a signal generator 310, a tester ATE input output (IO) channel 320, a transmission line 330, a time domain reflectometer 340, and one of the test sockets 220 of FIG. 2. Further, tester ATE IO channel 320 includes a signal driver 322 and a signal receiver 324.

In operation, signal generator 310 generates a test signal and transmits the test signal to signal driver 322 in tester ATE IO channel 320. In some embodiments, signal generator 310 generates a step test signal that causes the output of signal generator 310 to step up from zero volts (0 V) to three volts (3 V) with respect to ground 312. Additionally or alternatively, signal generator 310 generates a step test signal that causes the output of signal generator 310 to step from any first voltage to any other second voltage with respect to ground 312. Additionally or alternatively, signal generator 310 generates any other test signal that is suitable for time domain reflectometry at any technically feasible voltage.

Signal driver 322 included in tester ATE IO channel 320 receives the test signal from signal generator 310 and transmits the test signal to a transmission line 330. Transmission line 330 can be an electrical trace on a printed circuit board (PCB) of application loadboard 200, a wire or bundle of wires in a cable connected to application loadboard 200, and/or the like.

The test signal transmitted by signal driver 322 propagates along transmission line 330. Transmission line 330 is connected to a spring probe mounted on application loadboard 200 (not shown in FIG. 3). Application loadboard 200 includes a probe field with multiple spring probes. Each spring probe included in the probe field is configured to connect to a different pin of test socket 220. When test socket 220 is installed, each spring probe of the probe field can contract and/or expand to make contact with a different connection on a DUT. Similarly, each spring probe of the probe field can contract and/or expand to make contact with a different electrical signal trace on application loadboard 200. In this manner, the spring probes can carry signals, including test signals, between a reference DUT installed in test socket 220 and application loadboard 200.

When a test signal generated by signal generator 310 and transmitted by signal driver 322 through transmission line 330 reaches a spring probe installed on application loadboard 200 and/or a pin of test socket 220, the test signal is reflected back as a reflected TDR signal. The reflected TDR signal propagates along transmission line 330 until the reflected TDR signal reaches signal receiver 324 included in tester ATE IO channel 320. Signal receiver 324 receives the reflected TDR signal from transmission line 330 and transmits the reflected TDR signal to time domain reflectometer 340. The signal driver 322 is located proximate to the signal receiver 324, and the conjunction of the output of signal driver 322 and the input of signal receiver 324 is referred to as the observation point.

Time domain reflectometer 340 receives the reflected TDR signal from signal receiver 324 and can perform and/or facilitate various measurements of the reflected TDR signal including comparisons of the reflected TDR signal with the originally transmitted test signal. In that regard, time domain reflectometer 340 performs time domain reflectometry, which is a measurement technique used to determine the time for a test signal generated by signal generator 310 and transmitted by signal driver 322 to travel through transmission line 330 and to reflect back to signal receiver 324. This time is referred to as the propagation delay. Time domain reflectometer 340 can measure the propagation delay of test signals traveling through the electrical trace lines on application loadboard 200 and/or through the pins of test socket 220.

This technique of using time domain reflectometry to measure the propagation delay over the electrical trace lines of application loadboard 200 is referred to as fixture delay calibration. Time domain reflectometer 340 performs fixture delay calibration over several steps. In a first step, time domain reflectometer 340 measures a first propagation delay between the test signal transmitted by signal driver 322 and the reflected TDR signal received by signal receiver 324 when application loadboard 200 is in a disconnected state with respect to test socket 220. Time domain reflectometer 340 can convert this first propagation delay, referred to as a disconnected state propagation delay, into the distance from the signal driver 322 to the spring probe mounted on application loadboard 200. In a second step, time domain reflectometer 340 measures a second propagation delay between the test signal transmitted by signal driver 322 and the reflected TDR signal received by signal receiver 324 when application loadboard 200 is in a connected state with respect to test socket 220. Time domain reflectometer 340 can convert this second propagation delay, referred to as a connected state propagation delay, into the distance from the signal driver 322 to a pin of test socket 220 mounted on application loadboard 200. In a third step, time domain reflectometer 340 determines a third propagation delay by subtracting the first propagation delay (the disconnected propagation delay) from the second propagation delay (the connected propagation delay). Time domain reflectometer 340 can convert this third propagation delay, referred to as a test socket propagation delay, into the distance between the spring probe mounted on application loadboard 200 and test socket 220 mounted on application loadboard 200.

Further, time domain reflectometer 340 can include a TDR viewer that generates a 3D visualization of a waveform generated from the reflected TDR signal received from tester ATE IO channel 320. Time domain reflectometer 340 can display the 3D visualization on a display unit, such as display unit 125. From this 3D visualization, a test engineer can view the propagation delays as the test signal generated by signal generator 310 and transmitted by signal driver 322 propagates along transmission line 330 to application loadboard 200 and test socket 220. The test engineer can also view the propagation delays as the reflected TDR signal reflects off application loadboard 200 and test socket 220, propagates along transmission line 330, and arrives at signal receiver 324.

In some embodiments, each transmission line 330 can include various features including one or more layers of a PCB, one or more cable connectors, one or more PCB connectors, one or more vias on a PCB, and/or the like. These features can cause various distortions of the test signal and/or the reflected TDR signal. Further, each transmission line 330 can be subject to various damage modalities, including tears and nicks to wires shielded by cable, tears and nicks to electrical signal traces, vias, and layers on application loadboard 200, impedance mismatches, short circuits, open circuits, and/or the like. These damage modalities can also cause various distortions of the test signal and/or the reflected TDR signal. These distortions can be observed in the reflected TDR signal received by time domain reflectometer 340. Time domain reflectometer 340 can include a TDR viewer that generates a 3D visualization of a waveform generated from the reflected TDR signal received from tester ATE IO channel 320. Time domain reflectometer 340 can display the 3D visualization on a display unit, such as display unit 125. From this 3D visualization, a test engineer can view the signal distortions as the test signal generated by signal generator 310 and transmitted by signal driver 322 propagates along transmission line 330 through PCB layers, connectors, vias, through impedance mismatches, and through damaged areas, and arrives at application loadboard 200 and/or test socket 220. The test engineer can also view the propagation delays as the reflected TDR signal reflects off application loadboard 200 and test socket 220, propagates along transmission line 330 through PCB layers, connectors, vias, through impedance mismatches, and through damaged areas, and arrives at signal receiver 324. Indicia of distortion in the waveform that can indicate cause for further analysis include a slower than average or faster than average rise time, a later than average or sooner than average rise time, dips and peaks in the waveform, a waveform that remains at a constant voltage, and/or the like.

The test system can include multiple TDR test circuits 300 in order to simultaneously test multiple pins of a particular test socket 220 mounted at a test site of application loadboard 200. Further, the test system can include additional multiple TDR test circuits 300 in order to simultaneously test multiple pins of other test sockets 220 mounted at other test sites of application loadboard 200. Consequently, computing system 100 can include hundreds or thousands of instances of TDR test circuit 300 that concurrently generate test signals and perform time domain reflectometry on the reflected TDR signals of the generated test signals of multiple pins of multiple test sockets.

In that regard, TDR test circuit 300 can be replicated for each different spring probe mounted on application loadboard 200 and, correspondingly, for each different pin of test socket 220 that connects to a corresponding pin of a DUT. Time domain reflectometer 340 can simultaneously measure propagation delays associated with the multiple instances of TDR test circuit 300 to calibrate test fixture delays. Time domain reflectometer 340 can advance and/or delay test signals transmitted to the multiple signal drivers 322 so that all test signals transmitted by the multiple signal drivers 322 from multiple instances of tester ATE IO channel 320 arrive at respective pins of test socket 220 at the same time. In that regard, time domain reflectometer 340 can store the disconnected state propagation delays, connected state propagation delays, and/or test socket propagation delays in a database. Time domain reflectometer 340 can determine an average propagation delay for transmission lines 330 of the multiple tester ATE IO channels 320 connected to different pins of test socket 220. The average propagation delay can be a mean propagation delay, a median propagation delay, a mode propagation delay, and/or the like.

The test system implemented on computing system 100 can compare the average propagation delay with the individual propagation delays for each individual tester ATE IO channel 320. If a propagation delay for a particular tester ATE IO channel 320 is greater than the average propagation delay, then the test system can advance test signals transmitted to signal driver 322 for that tester ATE IO channel 320. The test system can advance the test signal by the difference between the propagation delay for the particular tester ATE IO channel 320 and the average propagation delay. If a propagation delay for a particular tester ATE IO channel 320 is less than the average propagation delay, then the test system can delay test signals transmitted to signal driver 322 for that tester ATE IO channel 320. The test system can delay the test signal by the difference between the average propagation delay and the propagation delay for the particular tester ATE IO channel 320. In this manner, test signals transmitted to the various signal drivers 322 in multiple tester ATE IO channels 320 can be calibrated to arrive at corresponding pins of test socket 220 at the same time.

Time domain reflectometer 340 can include a TDR viewer that generates a 3D visualization of multiple waveforms generated from reflected TDR signals received via multiple tester ATE IO channels 320. Via the TDR viewer, time domain reflectometer 340 can display the 3D visualization on a display unit, such as display unit 125. Time domain reflectometer 340 displays each waveform at a different offset from all other waveforms along one dimension of the 3D visualization. Further, time domain reflectometer 340 can receive user inputs to rotate, resize, pan, and zoom the 3D visualization in 3D space.

Time domain reflectometer 340 can display many, most, or all the reflected TDR waveforms for application loadboard 200 and/or test socket 220 simultaneously. Time domain reflectometer 340 receives reflected TDR signals from multiple transmission lines 330 connected to application loadboard 200 and/or test socket 220. From these reflected TDR signals, time domain reflectometer 340 generates waveforms associated with test signal propagation and delay, where each waveform corresponds to a different reflected TDR signal. Each waveform displays a test signal as the test signal propagates through a corresponding transmission line 330, including between PCB layers, connectors, and vias of application loadboard 200. As a result, the 3D visualization displays the various waveforms and indicates the associated performance of the corresponding reflected TDR signals visually. A test engineer can view the 3D visualization in order to determine if the waveform shows any deviations from expected and/or nominal values, shapes, and characteristics. With this 3D visualization of multiple reflected waveforms, a test engineer can measure propagation delays of various reflected TDR signals. Further, the test engineer can quickly identify and isolate certain TDR signals that indicate specific issues, defects, damage, and/or other problems. The test engineer can then determine what, if any, remedial action should be recommended, including repair of application loadboard 200 or test socket 220, replacement of application loadboard 200 or test socket 220, improvements in the manufacturing process of application loadboard 200 or test socket 220, alternatives to the electrical signal trace layout and/or cable construction of application loadboard 200 or test socket 220, and/or the like.

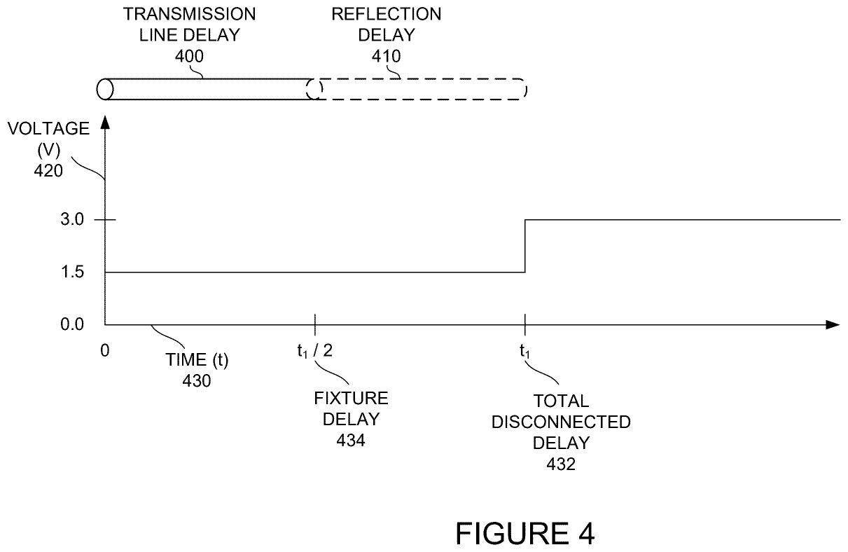

FIG. 4 illustrates how the TDR test circuit 300 of FIG. 3 can measure a propagation delay of a transmission line when the test socket is disconnected from the application loadboard, according to various embodiments. The graph illustrates the voltage 420 at the output of signal driver 322 and the input of signal receiver 324 over time 430. As described herein, signal generator 310 generates a test signal and transmits the test signal to signal driver 322 in tester ATE IO channel 320. In some embodiments, the test signal generated by signal generator 310 is a step signal that causes the output of signal generator 310 to step up from 0 to 3.0 V with respect to ground 312. The output impedance of signal driver 322 and the input impedance of transmission line 330 form a voltage divider based on the ratio of the output impedance and the input impedance. In some embodiments, the output impedance of signal driver 322 and the input impedance of transmission line 330 are the same. For example, the output impedance of signal driver 322 can be 50 ohms (50 Ω) and the input impedance of transmission line 330 can likewise be 50 Ω.

In such embodiments, the voltage of the test signal generated by signal generator 310 is divided evenly by the output of signal driver 322 and transmission line 330. Accordingly, at the point in time that the voltage of the test signal generated by signal generator 310 steps from 0 V to 3.0 V, one half of that voltage, or 1.5 V, is measured at the output of signal driver 322 and likewise at the input of signal receiver 324. The remaining 1.5 V of the test signal propagates along transmission line 330 until the test signal reaches a spring probe mounted on application loadboard 200. The test signal is then reflected back through transmission line 330 to the output of signal driver 322 and the input of signal receiver 324.

When the test signal reaches the output of signal driver 322 and the input of signal receiver 324, the voltage at that point increases from 1.5 V to 3.0 V. Time domain reflectometer 340 measures the total disconnected delay 432 from when the output of signal driver 322 steps from 0 V to 1.5 V until the time when the output of signal driver 322 steps from 1.5 V to 3.0 V. This time, identified as time t₁, represents the round-trip time for the test signal to propagate from the output of signal driver 322 through transmission line 330 and to reflect back through transmission line 330 to the input of signal receiver 324. Assuming that the propagation speed is the same in both directions, the transmission line delay 400 for the test signal to propagate from the output of signal driver 322 to the spring probe mounted on application loadboard 200 is equal to the reflection delay 410 for the reflected TDR signal to propagate from the spring probe mounted on application loadboard 200 to the input of signal receiver 324. Accordingly, the one-way fixture delay 434 is one half of the total disconnected delay 432, or t₁/2.

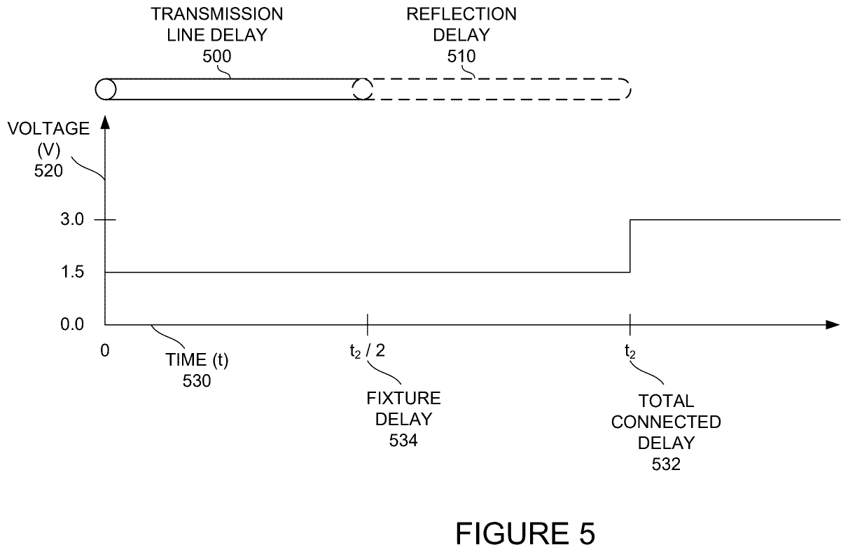

FIG. 5 illustrates how the TDR test circuit 300 of FIG. 3 can measure a propagation delay of a transmission line when the test socket is connected to the application loadboard, according to various embodiments. The graph illustrates the voltage 520 at the output of signal driver 322 and the input of signal receiver 324 over time 530. As described herein, signal generator 310 generates a test signal and transmits the test signal to signal driver 322 in tester ATE IO channel 320. In some embodiments, the test signal generated by signal generator 310 is a step signal that causes the output of signal generator 310 to step up from 0 to 3.0 V with respect to ground 312. The output impedance of signal driver 322 and the input impedance of transmission line 330 form a voltage divider based on the ratio of the output impedance and the input impedance. In some embodiments, the output impedance of signal driver 322 and the input impedance of transmission line 330 are the same. For example, the output impedance of signal driver 322 can be 50 Ω and the input impedance of transmission line 330 can likewise be 50 Ω.

In such embodiments, the voltage of the test signal generated by signal generator 310 is divided evenly by the output of signal driver 322 and transmission line 330. Accordingly, at the point in time that the voltage of the test signal generated by signal generator 310 steps from 0 V to 3.0 V, one half of that voltage, or 1.5 V, is measured at the output of signal driver 322 and likewise at the input of signal receiver 324. The remaining 1.5 V of the test signal propagates along transmission line 330 until the test signal reaches a pin of test socket 220 mounted on application loadboard 200. The test signal is then reflected back through transmission line 330 to the output of signal driver 322 and the input of signal receiver 324.

When the test signal reaches the output of signal driver 322 and the input of signal receiver 324, the voltage at that point increases from 1.5 V to 3.0 V. Time domain reflectometer 340 measures the total connected delay 532 from when the output of signal driver 322 steps from 0 V to 1.5 V until the time when the output of signal driver 322 steps from 1.5 V to 3.0 V. This time, identified as time t₂, represents the round-trip time for the test signal to propagate from the output of signal driver 322 through transmission line 330 and to reflect back through transmission line 330 to the input of signal receiver 324. Assuming that the propagation speed is the same in both directions, the transmission line delay 500 for the test signal to propagate from the output of signal driver 322 to test socket 220 mounted on application loadboard 200 is equal to the reflection delay 510 for the reflected TDR signal to propagate from test socket 220 mounted on application loadboard 200 to the input of signal receiver 324. Accordingly, the one-way fixture delay 534 is one half of the total connected delay 532, or t₂/2.

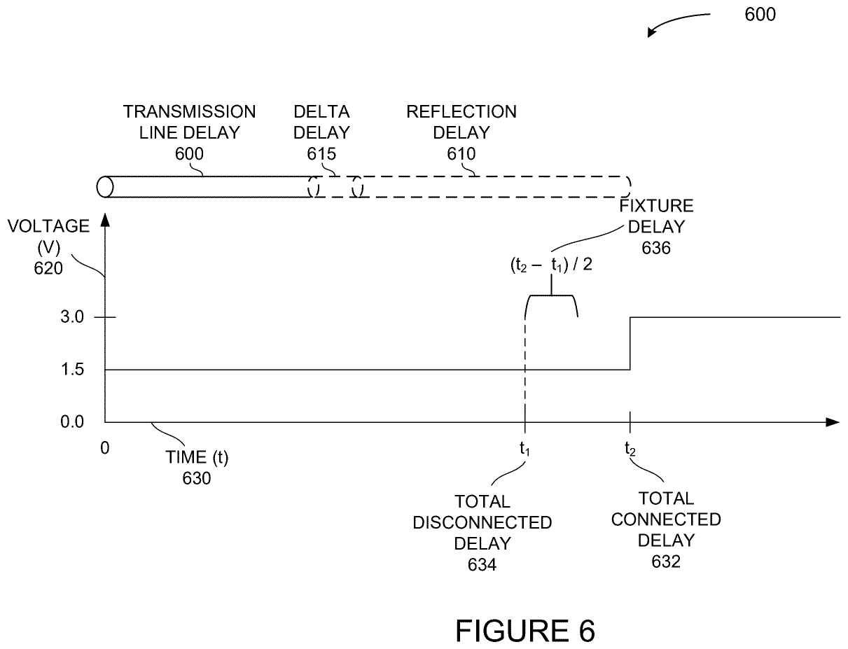

FIG. 6 illustrates how the TDR test circuit 300 of FIG. 3 can measure a propagation delay of the test socket connected to the application loadboard, according to various embodiments. The graph illustrates the voltage 620 at the output of signal driver 322 and the input of signal receiver 324 over time 630. As shown, transmission line delay 600 is the time for the test signal to propagate from the output of signal driver 322 to the spring probe mounted on application loadboard 200. Delta delay 615 is the round-trip time for the test signal to propagate from the spring probe mounted on application loadboard 200 to the pin on test socket 220 and reflect back to the spring probe. Reflection delay 610 is the time for the test signal to reflect back from the spring probe mounted on application loadboard 200 to the input of signal receiver 324. Time domain reflectometer 340 can determine this delta delay 615 by subtracting total disconnected delay 634, or t₁, from total connected delay 632, or t₂. Therefore, time domain reflectometer 340 determines delta delay 615 to be t₂−t₁. Assuming that the propagation speed is the same in both directions, the delay for the test signal to propagate from the spring probe mounted on application loadboard 200 to test socket 220 mounted on application loadboard 200 is equal to the reflection delay for the reflected TDR signal to propagate from test socket 220 mounted on application loadboard 200 to the spring probe mounted on application loadboard 200. Accordingly, the one-way fixture delay 636 is one half of the delta delay 615, or (t₂−t₁)/2.

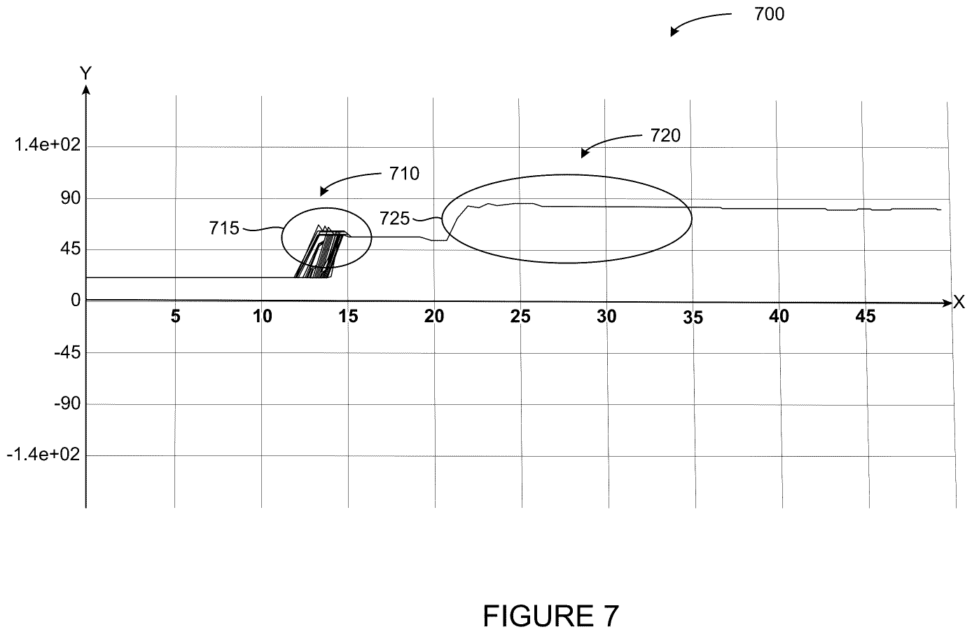

FIG. 7 is a 3D visualization 700 of reflected TDR signals when the application loadboard 200 is in a disconnected state, according to various embodiments. As shown, 3D visualization 700 displays the waveforms for the reflected TDR signals as a 2D projection, where the vertical dimension represents signal voltage and the horizontal dimension represents time. Region 710 of 3D visualization 700 corresponds to the time when the reflected TDR signals arrive at the spring probes mounted on application loadboard 200. Detail 715 illustrates waveforms for multiple reflected TDR signals have some amount of overshoot. However, because 3D visualization 700 is displayed as a 2D projection, the waveforms for the various reflected TDR signals are overlaid with one another, making it difficult to determine which reflected TDR signals have overshoot and which reflected TDR signals do not have overshoot.

Region 720 of 3D visualization 700 corresponds to the time when the reflected TDR signals arrive at the test site where the disconnected test socket 220 can be mounted on application loadboard 200. Detail 725 illustrates waveforms indicating that all of the reflected TDR signals have the same propagation delay as the other reflected TDR signals. Consequently, the reflected TDR signals arrive at respective spring probes of application loadboard 200 at the same time.

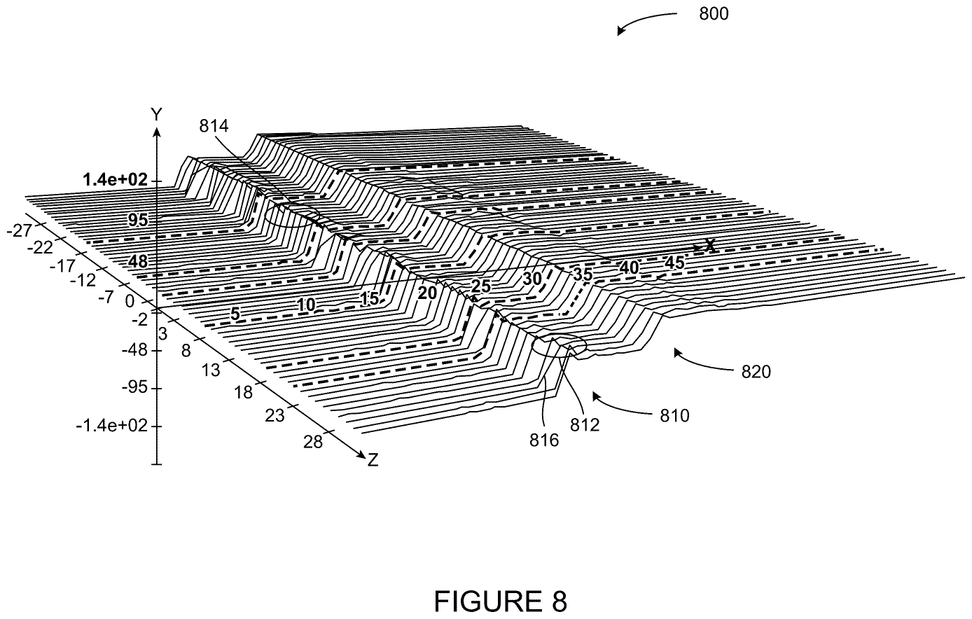

FIG. 8 is a 3D visualization 800 of the reflected TDR signals of FIG. 7 from an alternative view, according to various embodiments. With the alternative view of 3D visualization 800, specific reflected TDR signals with certain characteristics of interest can more readily by identified and isolated for further analysis. Region 810 of 3D visualization 800 corresponds to the time when the reflected TDR signals arrive at the spring probes mounted on application loadboard 200. Detail 812 illustrates waveforms for a first group of specific reflected TDR signals have some amount of overshoot. Detail 814 illustrates waveforms for a second group of specific reflected TDR signals do not have overshoot. The alternative view of 3D visualization 800 enables quick identification of reflected TDR signals that have overshoot, such as the reflected TDR signals shown in detail 812. Further, the alternative view of 3D visualization 800 enables quick identification of reflected TDR signals that do not have overshoot, such as the reflected TDR signals shown in detail 814. In addition, other areas of interest may be apparent in 3D visualization 800 that were not apparent in 3D visualization 700 of FIG. 7. For example, waveform 816 is for a reflected TDR signal that has a significantly longer rise time than other waveforms for other reflected TDR signals. The alternative view of 3D visualization 800 enables quick identification of such reflected TDR signals.

Region 820 of 3D visualization 800 corresponds to the time when the reflected TDR signals arrive at the test site where the disconnected test socket 220 can be mounted on application loadboard 200. The waveforms at region 820 are uniform during this time, indicating that 3D visualization 800 illustrates waveforms for reflected TDR signals when application loadboard 200 is in a disconnected state.

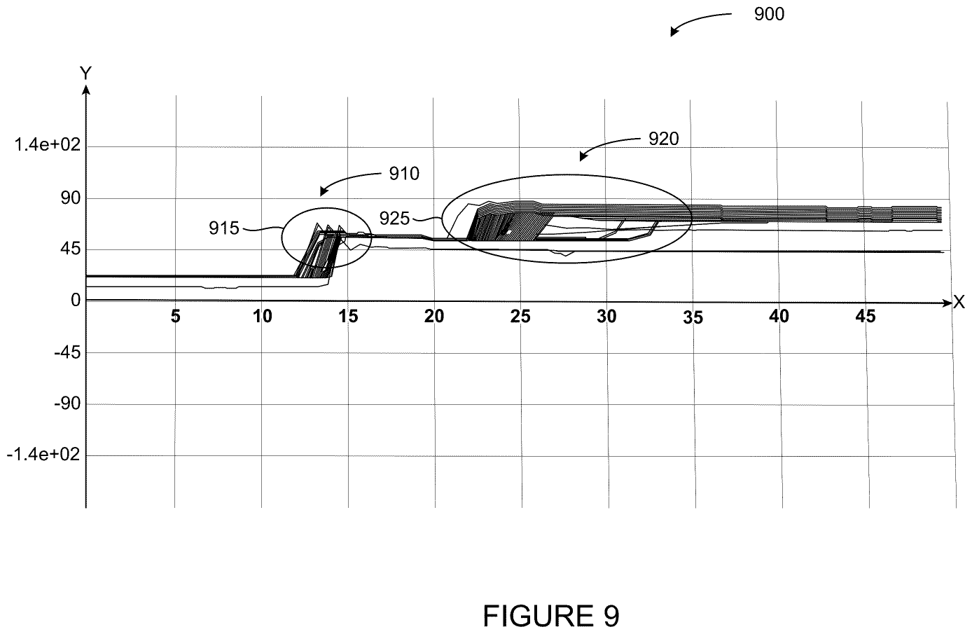

FIG. 9 is a 3D visualization 900 of reflected TDR signals when the application loadboard 200 is in a connected state, according to various embodiments. As shown, 3D visualization 900 displays the waveforms for the reflected TDR signals as a 2D projection, where the vertical dimension represents signal voltage and the horizontal dimension represents time. Region 910 of 3D visualization 900 corresponds to the time when the reflected TDR signals arrive at the spring probes mounted on application loadboard 200. Detail 915 illustrates waveforms for multiple reflected TDR signals have some amount of overshoot. However, because 3D visualization 900 is displayed as a 2D projection, the waveforms for the various reflected TDR signals are overlaid with one another, making it difficult to determine which reflected TDR signals have overshoot and which reflected TDR signals do not have overshoot.

Region 920 of 3D visualization 900 corresponds to the time when the reflected TDR signals arrive at the pins of test socket 220 mounted on application loadboard 200. Detail 925 illustrates waveforms indicating that some of the reflected TDR signals have a significantly longer propagation delay than other reflected TDR signals. Again, because 3D visualization 900 is displayed as a 2D projection, the waveforms for the various reflected TDR signals are overlaid with one another, making it difficult to determine which reflected TDR signals have shorter propagation delays and which reflected TDR signals have longer propagation delays.

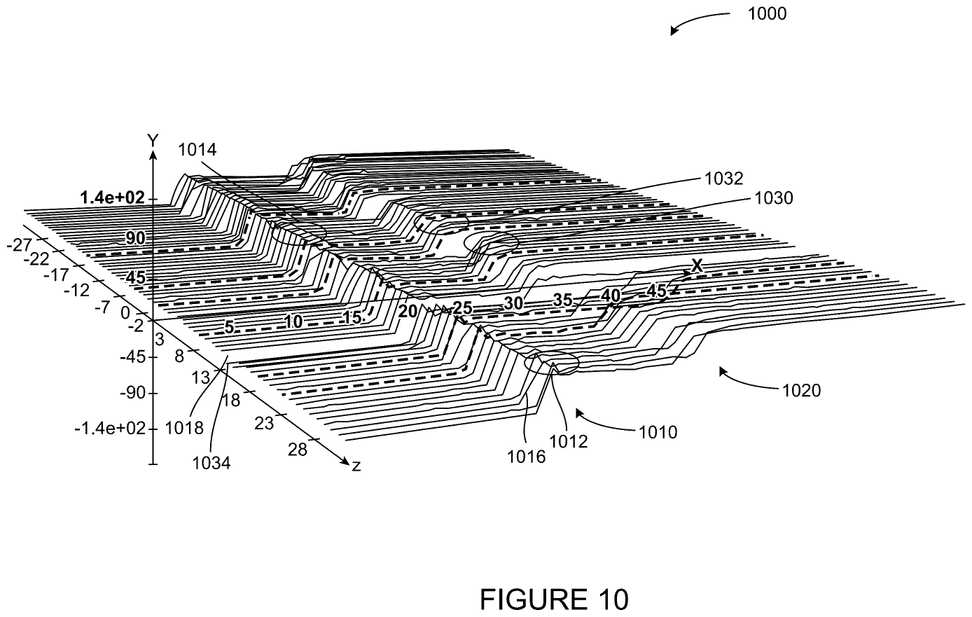

FIG. 10 is a 3D visualization 1000 of the reflected TDR signals of FIG. 9 from an alternative view, according to various embodiments. With the alternative view of 3D visualization 1000, specific reflected TDR signals with certain characteristics of interest can more readily by identified and isolated for further analysis. Region 1010 of 3D visualization 1000 corresponds to the time when the reflected TDR signals arrive at the spring probes mounted on application loadboard 200. Detail 1012 illustrates waveforms for a first group of specific reflected TDR signals have some amount of overshoot. Detail 1014 illustrates waveforms for a second group of specific reflected TDR signals do not have overshoot. The alternative view of 3D visualization 1000 enables quick identification of reflected TDR signals that have overshoot, such as the reflected TDR signals shown in detail 1012. Further, the alternative view of 3D visualization 1000 enables quick identification of reflected TDR signals that do not have overshoot, such as the reflected TDR signals shown in detail 1014. In addition, other areas of interest may be apparent in 3D visualization 1000 that were not apparent in 3D visualization 900 of FIG. 9. For example, waveform 1016 is for a reflected TDR signal that has a significantly longer rise time than other waveforms for other reflected TDR signals. Waveform 1018 is not present, indicating that the corresponding reflected TDR signal is for a transmission line 330 that has a short circuit. The alternative view of 3D visualization 1000 enables quick identification of such reflected TDR signals.

Region 1020 of 3D visualization 1000 corresponds to the time when the reflected TDR signals arrive at the pins of test socket 220 mounted on application loadboard 200. The waveforms at region 1020 are not uniform during this time, indicating that 3D visualization 1000 illustrates waveforms for reflected TDR signals when application loadboard 200 is in a connected state. Detail 1030 illustrates waveforms for a first group of specific reflected TDR signals have significantly more propagation delay relative to a second group of specific reflected TDR signals illustrated in detail 1032. Waveform 1034 rises at region 1010 but does not further rise at region 1020, indicating a short circuit of the corresponding reflected TDR signal at or near the spring probe. Again, the alternative view of 3D visualization 1000 enables quick identification of such reflected TDR signals.

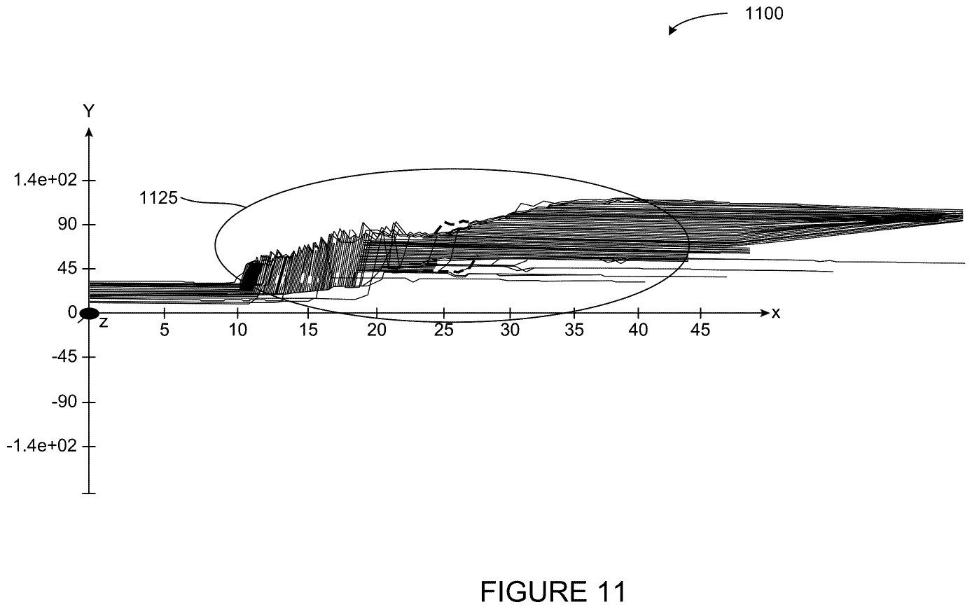

FIG. 11 is a 3D visualization 1100 of reflected TDR signals, according to various embodiments. As shown, 3D visualization 1100 displays the waveforms for the reflected TDR signals as a 2D projection, where the vertical dimension represents signal voltage and the horizontal dimension represents time. 3D visualization 1100 displays significantly more reflected TDR signals than 3D visualization 900 of FIG. 9. Further, detail 1125 illustrates waveforms with variable rise times over an extended period of time, making it difficult to determine which reflected TDR signals merit further analysis.

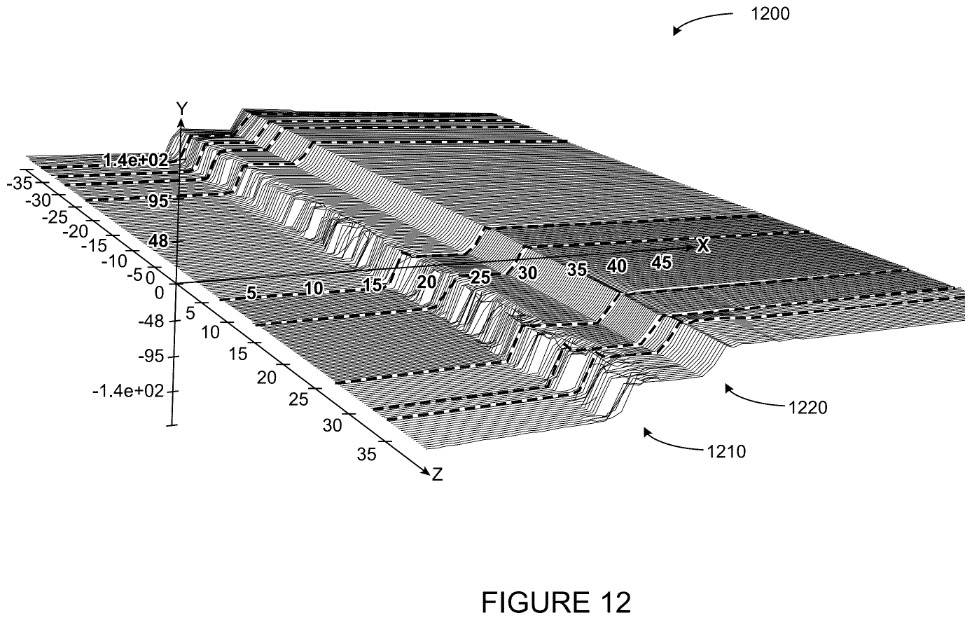

FIG. 12 is a 3D visualization 1200 of the reflected TDR signals of FIG. 11 from an alternative view when the application loadboard 200 is in a disconnected state, according to various embodiments. Similarly to 3D visualization 800 of FIG. 8, region 1210 of 3D visualization 1200 corresponds to the time when the reflected TDR signals arrive at the spring probes mounted on application loadboard 200. Region 1220 of 3D visualization 1200 corresponds to the time when the reflected TDR signals arrive at the test site where the disconnected test socket 220 can be mounted on application loadboard 200. The waveforms at region 1220 are uniform during this time, indicating that 3D visualization 1200 illustrates waveforms for reflected TDR signals when application loadboard 200 is in a disconnected state. Even though 3D visualization 1200 displays significantly more reflected TDR signals than 3D visualization 800 of FIG. 8, the alternative view of 3D visualization 1200 enables quick identification of reflected TDR signals that have overshoot, slower rise times, greater than average propagation delays, less than average propagation delays, and/or the like.

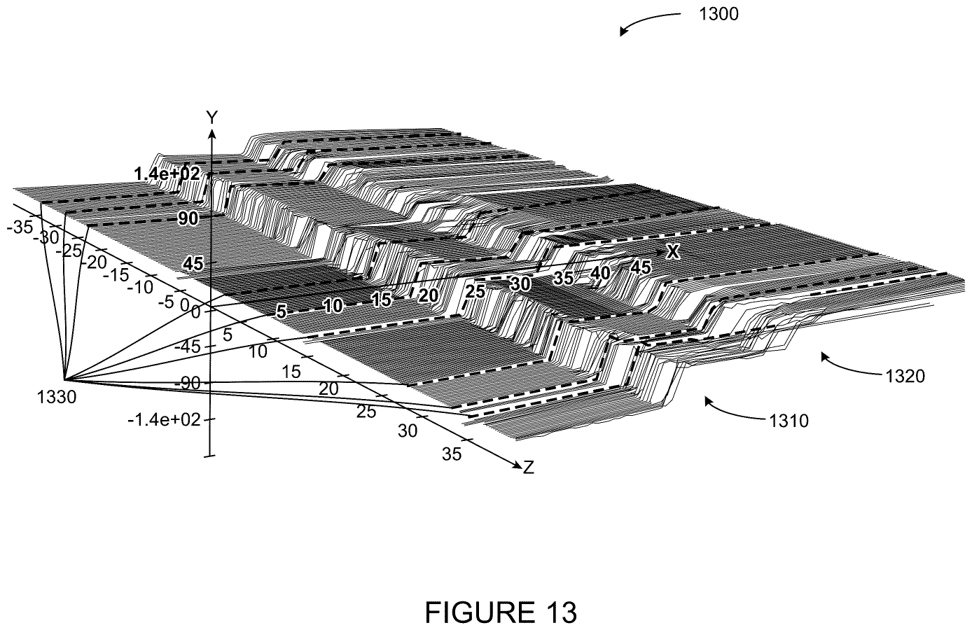

FIG. 13 is a 3D visualization 1300 of the reflected TDR signals of FIG. 11 from an alternative view when the application loadboard 200 is in a connected state, according to various embodiments. Similarly to 3D visualization 1000 of FIG. 10, region 1310 of 3D visualization 1300 corresponds to the time when the reflected TDR signals arrive at the spring probes mounted on application loadboard 200. Region 1320 of 3D visualization 1300 corresponds to the time when the reflected TDR signals arrive at the pins of test socket 220 mounted on application loadboard 200. The waveforms at region 1320 are not uniform during this time, indicating that 3D visualization 1300 illustrates waveforms for reflected TDR signals when application loadboard 200 is in a connected state. Even though 3D visualization 1300 displays significantly more reflected TDR signals than 3D visualization 1000 of FIG. 10, the alternative view of 3D visualization 1300 enables quick identification of reflected TDR signals that have overshoot, slower rise times, greater than average propagation delays, less than average propagation delays, short circuits, and/or the like.

In some embodiments, a subset of the waveforms for the reflected TDR signals can be selected for further analysis. As shown, such a subset of the waveforms can include waveforms and/or waveform groups 1330.

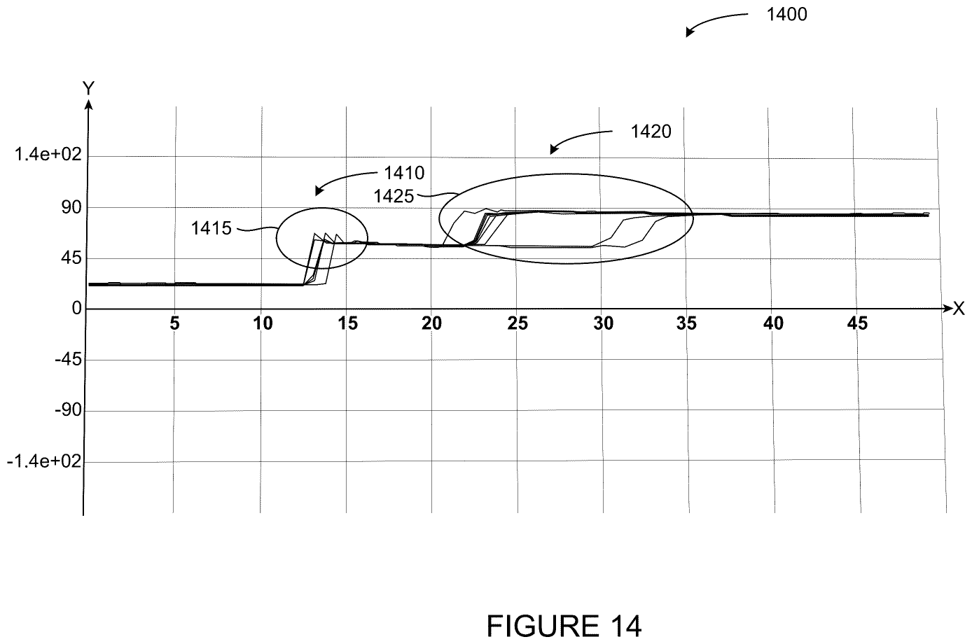

FIG. 14 is a 3D visualization 1400 of a subset of the reflected TDR signals of FIG. 13, according to various embodiments. After selecting waveforms and/or waveform groups 1330 of 3D visualization 1300, time domain reflectometer 340 can apply a filter to display the selected waveforms and/or waveform groups 1330 and to refrain from displaying other waveforms and/or waveform groups of 3D visualization 1300 that are not selected. 3D visualization 1400 displays these selected waveforms and/or waveform groups 1330 for the selected reflected TDR signals as a 2D projection, where the vertical dimension represents signal voltage and the horizontal dimension represents time. Region 1410 of 3D visualization 1400 corresponds to the time when the reflected TDR signals arrive at the spring probes mounted on application loadboard 200. Detail 1415 illustrates waveforms for multiple reflected TDR signals have some amount of overshoot. However, because 3D visualization 1400 is displayed as a 2D projection, the waveforms for the various reflected TDR signals are overlaid with one another, making it difficult to determine which reflected TDR signals have overshoot and which reflected TDR signals do not have overshoot.

Region 1420 of 3D visualization 1400 corresponds to the time when the reflected TDR signals arrive at the pins of test socket 220 mounted on application loadboard 200. Detail 1425 illustrates waveforms indicating that some of the reflected TDR signals have a significantly longer propagation delay than other reflected TDR signals. Again, because 3D visualization 1400 is displayed as a 2D projection, the waveforms for the various reflected TDR signals are overlaid with one another, making it difficult to determine which reflected TDR signals have shorter propagation delays and which reflected TDR signals have longer propagation delays.

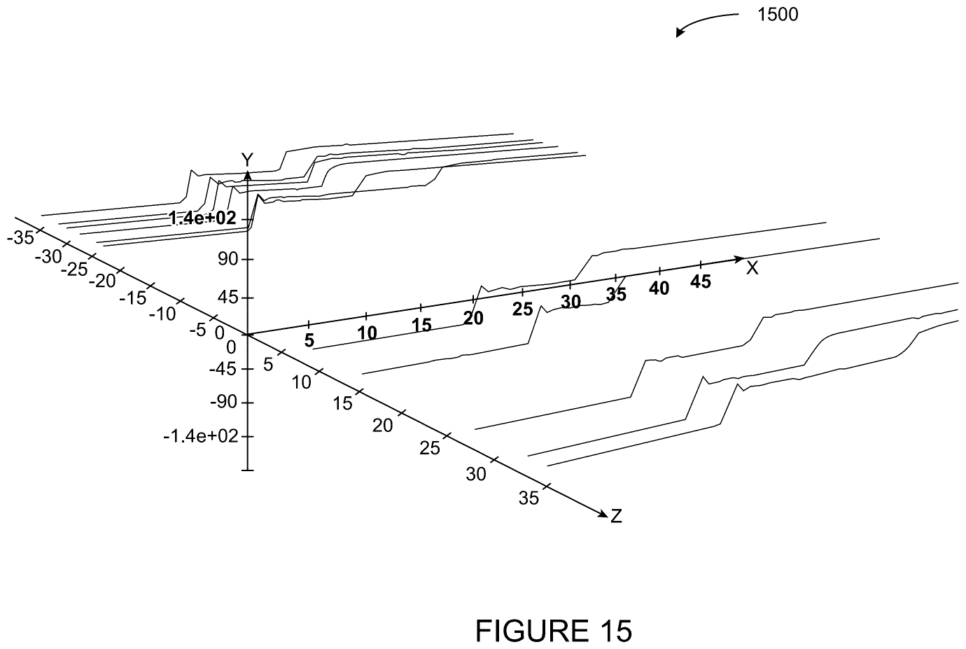

FIG. 15 is a 3D visualization 1500 of the subset of the reflected TDR signals of FIG. 14 from an alternative view, according to various embodiments. As described in conjunction with FIGS. 8, 10, and 12-13, with the alternative view of 3D visualization 1500, specific reflected TDR signals with certain characteristics of interest can more readily by identified and isolated for further analysis.

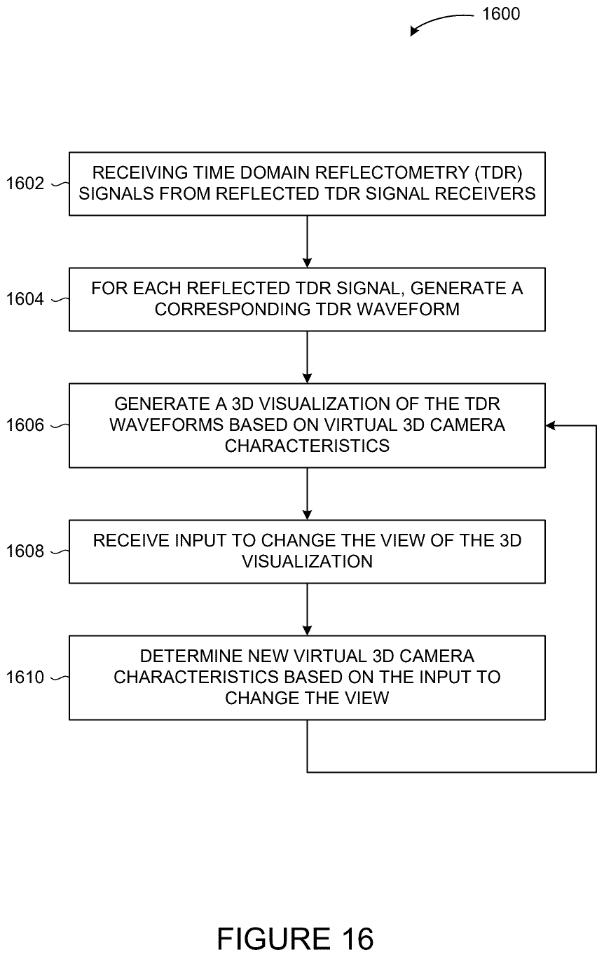

FIG. 16 is a flow diagram of methods steps for generating a 3D visualization of reflected time domain reflectometry signals with the test system of FIGS. 1-3, according to various embodiments. Although the method steps are described in conjunction with the systems of FIGS. 1-15, persons of ordinary skill in the art will understand that any system configured to perform the method steps, in any order, is within the scope of the present disclosure.

As shown, a method 1600 begins at step 1602, where a time domain reflectometer included in a test system, such as time domain reflectometer 340 of FIG. 3, receives time domain reflectometry (TDR) signals from reflected TDR signal receivers. A signal generator included in the test system generates a test signal and transmits the test signal to multiple signal drivers. The signal drivers transmit the test signal through respective transmission lines to corresponding spring probes installed on an application loadboard and/or to corresponding pins of one or more test sockets. The test signals are then reflected back as TDR signals. The reflected TDR signals propagate along the respective transmission lines until the reflected TDR signals reach corresponding signal receivers. The signal receivers receive the reflected TDR signals from respective transmission lines and transmit the reflected TDR signals to the time domain reflectometer.

At step 1604, for each reflected TDR signal, the time domain reflectometer generates a corresponding TDR waveform. The time domain reflectometer can use the waveforms generated from the reflected TDR signals to perform and/or facilitate various measurements of the reflected TDR signals including comparisons of the reflected TDR signals with the originally transmitted test signal. Each waveform displays a test signal as the test signal propagates from a signal driver through a corresponding transmission line, including between PCB layers, connectors, and vias of the application loadboard and/or test socket and as the test signal is reflected back to a signal receiver.

At step 1606, the time domain reflectometer generates a 3D visualization of the TDR waveforms based on virtual 3D camera characteristics. The time domain reflectometer can include a TDR viewer that generates a 3D visualization of multiple waveforms generated from reflected TDR signals received via multiple signal receivers. The virtual 3D camera characteristics can include a 3D location, a 3D viewing direction, a zoom/magnification value, and/or the like. The virtual 3D camera characteristics define the viewing location, the viewing angle, the size, and/or other parameters related to viewing the 3D visualization. Via the TDR viewer, the time domain reflectometer can display the 3D visualization on a display unit. The time domain reflectometer displays each waveform at a different offset from all other waveforms along one dimension of the 3D visualization. As a result, the 3D visualization simultaneously displays the various waveforms and indicates the associated performance of the corresponding reflected TDR signals.

At step 1608, the time domain reflectometer receives input to change the view of the 3D visualization. The input can cause the time domain reflectometer to rotate, resize, pan, and zoom the 3D visualization in 3D space.

At step 1610, the time domain reflectometer determines new virtual 3D camera characteristics based on the input to change the view. Based on the input received at step 1608, The time domain reflectometer determines one or more changes to the current virtual 3D camera characteristics, such as changes to the 3D location, the 3D viewing direction, the zoom/magnification value, and/or the like. The method 1600 then returns to step 1606 to generate a 3D visualization of the TDR waveforms based on the new virtual 3D camera characteristics.

In sum, the disclosed techniques include a TDR viewer for visualizing a large number of reflected TDR signals on a 3D display system. The TDR system captures the waveforms for reflected TDR signals that are associated with signal propagation and delay. The TDR viewer displays the signal waveforms as the signals propagate through the transmission lines. The waveforms can display changes in the reflected TDR signals due to transmission between various printed circuit board layers, through component connectors and vias of the printed circuit board, and across the interconnects and socket pins. The 3D visualization of the reflected TDR signals can be rotated in 3D space, zoomed in or out, and filtered to display a subset of signals.

At least one technical advantage of the disclosed techniques relative to the prior art is that, with the disclosed techniques, a test engineer can visually observe myriad waveforms concurrently in 3D space. The 3D visualization techniques enable the test engineer to more quickly identify TDR signals of interest, including signals with longer or shorter delay times relative to other TDR signals, signals that exhibit undesirable signal attributes, and/or the like. More specifically, the test engineer can determine if the waveform deviates from a nominal value visually and can determine if the manufacturing process should be improved, whether the printed circuit board and/or interconnects should be repaired or replaced, whether the layout of the transmission lines on the printed circuit board should change, whether the timing of one or more transmitters should be adjusted and/or the like.

Further, the TDR viewer allows the test engineer to select individual transmission lines and/or groups of transmission lines separately, thereby enabling the test engineer to easily compare waveforms for certain transmission lines of interest. The test engineer can quickly identify whether an unusual waveform is indicative of manufacturing issues, layout issues, printed circuit board quality issues, and/or the like. As a result, the test engineer can more quickly and efficiently identify and resolve transmission line problems relative to prior conventional approaches. This improves efficiency in engineering environment and productivity in manufacturing process. This improved efficiency can lead to reduced manufacturing test time, increased utilization of test equipment, reduced power consumption of test equipment, and, therefore, reduced testing cost. These advantages represent one or more technological improvements over prior art approaches.

1. According to some embodiments, a method, comprises: receiving a first plurality of time domain reflectometry (TDR) signals from a test system; generating, for each TDR signal included the first plurality of TDR signals, a corresponding waveform included in a first plurality of waveforms; and generating a three-dimensional (3D) visualization of the first plurality of waveforms, wherein each waveform included in the first plurality of waveforms is at a different offset from all other waveforms included in the first plurality of waveforms along one dimension of the 3D visualization.

2. The method according to clause 1, further comprising: transmitting a test signal from a signal driver through a transmission line, wherein: a first TDR signal included in the first plurality of TDR signals comprises a reflection of the test signal, and a first waveform included in the first plurality of waveforms corresponding to the first TDR signal is used to determine a time for the first TDR signal to propagate from the signal driver through a transmission line and to reflect back to a signal receiver that is proximate to the signal driver.

3. The method according to clause 1 or clause 2, further comprising: transmitting a test signal from a signal driver through an electrical trace line on an application loadboard included in a test system, wherein: a first TDR signal included in the first plurality of TDR signals comprises a reflection of the test signal, and a first waveform included in the first plurality of waveforms corresponding to the first TDR signal is used to determine a delay associated with the electrical trace line.

4. The method according to any of clauses 1-3, wherein the delay comprises a propagation delay for the first TDR signal to propagate through the electrical trace line on the application loadboard.

5. The method according to any of clauses 1-4, further comprising: transmitting a first test signal from a signal driver to a test fixture included in a test system, wherein: a first TDR signal included in the first plurality of TDR signals comprises a reflection of the first test signal, and a first waveform included in the first plurality of waveforms corresponding to the first TDR signal is used to calibrate a first propagation delay associated with the test fixture.

6. The method according to any of clauses 1-5, wherein: the test fixture comprises an application loadboard and a test socket, the first test signal is transmitted from the signal driver to the application loadboard when the test socket is disconnected from the application loadboard, and the first waveform is used to measure a second propagation delay from the signal driver to the application loadboard.

7. The method according to any of clauses 1-6, wherein the second propagation delay is used to determine a distance from the signal driver a spring probe mounted on the application loadboard.

8. The method according to any of clauses 1-7, further comprising: transmitting a second test signal from the signal driver to the test fixture when the test socket is connected to the application loadboard, wherein: a second TDR signal included in a second plurality of TDR signals comprises a reflection of the second test signal, and a second waveform included in a second plurality of waveforms corresponding to the second TDR signal is used to measure a third propagation delay from the signal driver to the test socket.

9. The method according to any of clauses 1-8, wherein the third propagation delay is used to determine a distance from the signal driver to the test socket connected to the application loadboard.

10. The method according to any of clauses 1-9, wherein the first propagation delay is determined by subtracting the second propagation delay from the third propagation delay.

11. The method according to any of clauses 1-10, wherein: a first waveform included in the first plurality of waveforms corresponding to a first TDR signal included in the first plurality of TDR signals, and the first waveform is associated with at least one of a signal propagation of the first TDR signal or a delay of the first TDR signal.

12. The method according to any of clauses 1-11, further comprising: transmitting a test signal from a signal driver through an electrical trace line, wherein: a first TDR signal included in the first plurality of TDR signals comprises a reflection of the test signal, and the 3D visualization displays a first waveform included in the first plurality of waveforms corresponding to a first TDR signal included in the first plurality of TDR signals as the first TDR signal propagates through the electrical trace line.

13. The method according to any of clauses 1-12, wherein: the electrical trace line is on an application loadboard, and the 3D visualization displays the first waveform as the first TDR signal propagates through one or more layers of the application loadboard.

14. The method according to any of clauses 1-13, wherein: the electrical trace line is on an application loadboard, and the 3D visualization displays the first waveform as the first TDR signal propagates through one or more connectors of the application loadboard.

15. The method according to any of clauses 1-14, wherein: the electrical trace line is on an application loadboard, and the 3D visualization displays the first waveform as the first TDR signal propagates through one or more vias of the application loadboard.

16. The method according to any of clauses 1-15, further comprising: receiving a selection of a subset of waveforms included in the first plurality of waveforms; and modifying the three-dimensional (3D) visualization to display the subset of waveforms and refrain from displaying waveforms included in the first plurality of waveforms that are excluded from the subset of waveforms.

17. According to some embodiments, a test system comprises: an application loadboard configured to receive a test socket to which a reference device under test (DUT) can be mounted; and a time domain reflectometer that: receives a first plurality of time domain reflectometry (TDR) signals from the application loadboard; generating, for each TDR signal included the first plurality of TDR signals, a corresponding waveform included in a first plurality of waveforms; and generating a three-dimensional (3D) visualization of the first plurality of waveforms, wherein each waveform included in the first plurality of waveforms is at a different offset from all other waveforms included in the first plurality of waveforms along one dimension of the 3D visualization.

18. The test system according to clause 17, further comprising: a signal driver that transmits a first test signal to the application loadboard when the test socket is disconnected from the application loadboard, wherein the first waveform is used to measure a second propagation delay from the signal driver to the application loadboard.

19. The test system according to clause 17 or clause 18, further comprising: a test socket that is connected to the application loadboard, wherein: the signal driver transmits a second test signal to the application loadboard when the test socket is connected to the application, a second TDR signal included in a second plurality of TDR signals comprises a reflection of the second test signal, and a second waveform included in a second plurality of waveforms corresponding to the second TDR signal is used to measure a third propagation delay from the signal driver to the test socket.

20. The test system according to any of clauses 17-19, wherein the first propagation delay is determined by subtracting the second propagation delay from the third propagation delay.

Any and all combinations of any of the claim elements recited in any of the claims and/or any elements described in this application, in any fashion, fall within the contemplated scope of the present disclosure and protection.

Various modules of the disclosed system can access computer readable media, and the term is known or understood to include removable media, for example, Secure Digital (SD) cards, compact discs (CDs), digital versatile disc (DVD) ROM disks, and/or the like, as well as non-removable or internal media, for example, hard disks drives (HDDs), solid state drives (SSDs), RAM, ROM, flash memory, and/or the like.

Although the disclosure has been shown and described with respect to a certain exemplary embodiment or embodiments, equivalent alterations and modifications will occur to others skilled in the art upon the reading and understanding of this specification and the annexed drawings. In particular regard to the various functions performed by the above described components (assemblies, devices, etc.) the terms (including a reference to a “means”) used to describe such components are intended to correspond, unless otherwise indicated, to any component which performs the specified function of the described component (e.g., that is functionally equivalent), even though not structurally equivalent to the disclosed structure which performs the function in the herein illustrated exemplary embodiments of the disclosure. In addition, while a particular feature of the disclosure may have been disclosed with respect to only one of several embodiments, such feature may be combined with one or more features of the other embodiments as may be desired and advantageous for any given or particular application. Persons of ordinary skill in the art will appreciate that the architecture described in the figures in no way limits the scope of the various embodiments of the present disclosure.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer.” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, field-programmable gate arrays, and/or the like.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A method, comprising:
receiving a first plurality of time domain reflectometry (TDR) signals from a test system;
generating, for each TDR signal included the first plurality of TDR signals, a corresponding waveform included in a first plurality of waveforms; and
generating a three-dimensional (3D) visualization of the first plurality of waveforms,
wherein each waveform included in the first plurality of waveforms is at a different offset from all other waveforms included in the first plurality of waveforms along one dimension of the 3D visualization.

2. The method of claim 1, further comprising:
transmitting a test signal from a signal driver through a transmission line, wherein:
a first TDR signal included in the first plurality of TDR signals comprises a reflection of the test signal, and
a first waveform included in the first plurality of waveforms corresponding to the first TDR signal is used to determine a time for the first TDR signal to propagate from the signal driver through a transmission line and to reflect back to a signal receiver that is proximate to the signal driver.

3. The method of claim 1, further comprising:
transmitting a test signal from a signal driver through an electrical trace line on an application loadboard included in a test system,
wherein:
a first TDR signal included in the first plurality of TDR signals comprises a reflection of the test signal, and
a first waveform included in the first plurality of waveforms corresponding to the first TDR signal is used to determine a delay associated with the electrical trace line.

4. The method of claim 3, wherein the delay comprises a propagation delay for the first TDR signal to propagate through the electrical trace line on the application loadboard.

5. The method of claim 1, further comprising:
transmitting a first test signal from a signal driver to a test fixture included in a test system,
wherein:
a first TDR signal included in the first plurality of TDR signals comprises a reflection of the first test signal, and
a first waveform included in the first plurality of waveforms corresponding to the first TDR signal is used to calibrate a first propagation delay associated with the test fixture.

6. The method of claim 5, wherein:
the test fixture comprises an application loadboard and a test socket,
the first test signal is transmitted from the signal driver to the application loadboard when the test socket is disconnected from the application loadboard, and
the first waveform is used to measure a second propagation delay from the signal driver to the application loadboard.

7. The method of claim 6, wherein the second propagation delay is used to determine a distance from the signal driver a spring probe mounted on the application loadboard.

8. The method of claim 6, further comprising:
transmitting a second test signal from the signal driver to the test fixture when the test socket is connected to the application loadboard,
wherein:
a second TDR signal included in a second plurality of TDR signals comprises a reflection of the second test signal, and
a second waveform included in a second plurality of waveforms corresponding to the second TDR signal is used to measure a third propagation delay from the signal driver to the test socket.

9. The method of claim 8, wherein the third propagation delay is used to determine a distance from the signal driver to the test socket connected to the application loadboard.

10. The method of claim 8, wherein the first propagation delay is determined by subtracting the second propagation delay from the third propagation delay.

11. The method of claim 1, wherein:
a first waveform included in the first plurality of waveforms corresponding to a first TDR signal included in the first plurality of TDR signals, and
the first waveform is associated with at least one of a signal propagation of the first TDR signal or a delay of the first TDR signal.

12. The method of claim 11, further comprising:
transmitting a test signal from a signal driver through an electrical trace line,
wherein:
a first TDR signal included in the first plurality of TDR signals comprises a reflection of the test signal, and
the 3D visualization displays a first waveform included in the first plurality of waveforms corresponding to a first TDR signal included in the first plurality of TDR signals as the first TDR signal propagates through the electrical trace line.

13. The method of claim 12, wherein:
the electrical trace line is on an application loadboard, and
the 3D visualization displays the first waveform as the first TDR signal propagates through one or more layers of the application loadboard.

14. The method of claim 12, wherein:
the electrical trace line is on an application loadboard, and
the 3D visualization displays the first waveform as the first TDR signal propagates through one or more connectors of the application loadboard.

15. The method of claim 12, wherein:
the electrical trace line is on an application loadboard, and
the 3D visualization displays the first waveform as the first TDR signal propagates through one or more vias of the application loadboard.

16. The method of claim 1, further comprising:
receiving a selection of a subset of waveforms included in the first plurality of waveforms; and
modifying the three-dimensional (3D) visualization to display the subset of waveforms and refrain from displaying waveforms included in the first plurality of waveforms that are excluded from the subset of waveforms.

17. A test system, comprising:
an application loadboard configured to receive a test socket to which a reference device under test (DUT) can be mounted; and
a time domain reflectometer that:
receives a first plurality of time domain reflectometry (TDR) signals from the application loadboard;
generating, for each TDR signal included the first plurality of TDR signals, a corresponding waveform included in a first plurality of waveforms; and
generating a three-dimensional (3D) visualization of the first plurality of waveforms,
wherein each waveform included in the first plurality of waveforms is at a different offset from all other waveforms included in the first plurality of waveforms along one dimension of the 3D visualization.

18. The test system of claim 17, further comprising:
a signal driver that transmits a first test signal to the application loadboard when the test socket is disconnected from the application loadboard,
wherein the first waveform is used to measure a second propagation delay from the signal driver to the application loadboard.

19. The test system of claim 18, further comprising:
a test socket that is connected to the application loadboard,
wherein:
the signal driver transmits a second test signal to the application loadboard when the test socket is connected to the application,
a second TDR signal included in a second plurality of TDR signals comprises a reflection of the second test signal, and
a second waveform included in a second plurality of waveforms corresponding to the second TDR signal is used to measure a third propagation delay from the signal driver to the test socket.

20. The test system of claim 19, wherein the first propagation delay is determined by subtracting the second propagation delay from the third propagation delay.
